(19) United States
(12) Patent Application Publication
(10) Pub. No.: US 2017/0288641 A1
(43) Pub. Date: Oct. 5, 2017

(54) BAW FILTER AND METHOD FOR MANUFACTURING THE SAME

(71) Applicant: Samsung Electro-Mechanics Co., Ltd., Suwon-si (KR)

(72) Inventors: Han Tae KIM, Suwon-si (KR); Hyun Min HWANG, Suwon-si (KR); Jong Beom KIM, Suwon-si (KR); Seung Joo SHIN, Suwon-si (KR)

(73) Assignee: Samsung Electro-Mechanics Co., Ltd., Suwon-si (KR)

(21) Appl. No.: 15/420,722

(22) Filed: Jan. 31, 2017

(30) Foreign Application Priority Data
Apr. 4, 2016 (KR) 10-2016-0040815

(51) Int. Cl. H03H 9/70; H03H 9/54

(52) U.S. Cl. CPC H03H 9/46; H03H 3/007

(57) ABSTRACT

A bulk acoustic wave (BAW) filter includes: a substrate including a first mounting region and a second mounting region which are spaced apart from each other; a first fixing member disposed adjacent to the first mounting region; a second fixing member disposed adjacent to the second mounting region; a Tx filter mounted on the first mounting region and fixed by the first fixing member; and an Rx filter mounted on the second mounting region and fixed by the second fixing member.

### CROSS-REFERENCE TO RELATED APPLICATIONS

This application claims the benefit under 35 USC 119(a) of Korean Patent Application No. 10-2016-0040815, filed on Apr. 4, 2016 in the Korean Intellectual Property Office, the entire disclosure of which is incorporated herein by reference for all purposes.

### BACKGROUND

### 1. Field

The following description relates to a bulk acoustic wave (BAW) filter which may be manufactured to be compact in size and may improve product yield by having improved mounting characteristics. The following description further relates to a method for manufacturing the BAW filter.

### 2. Description of Related Art

In general, a bulk acoustic wave (BAW) filter is an element that passes a desired frequency band among radio frequency (RF) signals in a front end module of a device, such as a smartphone or a tablet, and blocks an unwanted frequency band among the RF signals. Demand for BAWs has been gradually increasing, in accordance with the growth of the mobile device market.

The BAW filter may be a BAW duplexer including one transmission (Tx) filter and one reception (Rx) filter, or a BAW quadplexer including two Tx filters and two Rx filters, respectively.

A high performance, small BAW filter has recently been preferred, and the availability of a single supply size of the BAW duplexer has gradually decreased. In particular, in the case in which a Tx filter and an Rx filter have been manufactured to be separate from each other and are disposed in a narrow space, interference between the Tx filter and the Rx filter may occur. Additionally, since the single supply weight of both the Tx filter and the Rx filter is light, there is a disadvantage that the Tx filter or the Rx filter may be disposed outside of a defined mounting region when mounted on the mounting region using surface mounting technology (SMT), or a pad of a substrate and a pad of the filter may become misaligned with each other. As a result, a problem of a process yield being degraded arises.

In order to avoid the above-mentioned problems, two filters may be mounted on a wider area. However, in such a case, since the mounted filters occupy more space, there is a disadvantage of the area of a printed circuit board (PCB) being increased.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic wave (BAW) filter includes: a substrate including a first mounting region and a second mounting region which are spaced apart from each other; a first fixing member disposed adjacent to the first mounting region; a second fixing member disposed adjacent to the second mounting region; a Tx filter mounted on the first mounting region and fixed by the first fixing member; and an Rx filter mounted on the second mounting region and fixed by the second fixing member.

The first fixing member may fix two sides of the Tx filter which are not adjacent to each other. The second fixing member may fix two sides of the Rx filter which are not adjacent to each other.

The first fixing member may fix two corners of the Tx filter which are not adjacent to each other. The second fixing member may fix two corners of the Rx filter which are not adjacent to each other.

The first fixing member may fix corners of the Tx filter. The second fixing member may fix corners of the Rx filter.

Pads formed on the first mounting region may be electrically connected to respective pads on the Tx filter. Pads formed on the second mounting region may be electrically connected to respective pads on the Rx filter.

The first fixing member may include a conductive material. The Tx filter may include a first ground electrode formed on a side of the Tx filter and electrically connected to the first fixing member.

The second fixing member may include a conductive material. The Rx filter may include a second ground electrode formed on a side of the Rx filter and electrically connected to the second fixing member.

The BAW filter may further include a molding part formed on the substrate and surrounding the Tx filter and the Rx filter.

The first fixing member and the second fixing member may include bodies having a bracket form.

The first fixing member and the second fixing member may include bodies having a rectangular form.

In another general aspect, a method to manufacture a bulk acoustic wave (BAW) filter includes: preparing a substrate including a first mounting region and a second mounting region which are spaced apart from each other, a first fixing member disposed adjacent to the first mounting region, and a second fixing member disposed adjacent to the second mounting region; mounting a Tx filter on the first mounting region, such that the Tx filter is fixed by the first fixing member; mounting an Rx filter on the second mounting region, such that the Rx filter is fixed by the second fixing member; and performing soldering for the substrate.

In the mounting of the Tx filter, the first fixing member may fix two sides of the Tx filter which are not adjacent to each other. In the mounting of the Rx filter, the second fixing member may fix two sides of the Rx filter which are not adjacent to each other.

In the mounting of the Tx filter, the first fixing member may fix two corners of the Tx filter which are not adjacent to each other. In the mounting of the Rx filter, the second fixing member may fix two corners of the Rx filter which are not adjacent to each other.

In the mounting of the Tx filter, the first fixing member may fix all corners of the Tx filter. In the mounting of the Rx filter, the second fixing member may fix all corners of the Rx filter.

The performing of the soldering for the substrate may include: electrically connecting pads on the first mounting region to pads on the Tx filter, by solder; and electrically connecting pads on the second mounting region to pads on the Rx filter, by the solder.

The performing of the soldering for the substrate may include: electrically connecting the first fixing member and a first ground electrode, formed on a side of the Tx filter, to each other.

The performing of the soldering for the substrate may include: electrically connecting the second fixing member and a second ground electrode, formed on a side of the Rx filter, to each other.

The method may further include forming a molding part on the substrate such that the molding part surrounds the Tx filter and the Rx filter.

Other features and aspects will be apparent from the following detailed description, the drawings, and the claims.

### BRIEF DESCRIPTION OF DRAWINGS

FIGS. 1A and 1B are an exterior perspective view and a cross-sectional view taken on a line A1-A1, respectively, of a BAW filter, according to an embodiment.

FIGS. 2A through 2C are exploded views illustrating example of a structures of the BAW filter.

FIGS. 3A, 3B and 3C are a cross-sectional view, a side view, and a bottom view, respectively, illustrating an example of a structure of the BAW filter.

FIGS. 4A and 4B are a side view illustrating an example of a structure of a substrate and a top view illustrating an example of a mounting region of the substrate, respectively.

FIG. 5 is a flowchart illustrating a method for manufacturing a BAW filter, according to an embodiment.

FIG. 6 is a view illustrating an operation of preparing a substrate, according to an embodiment.

FIG. 7 is a view illustrating an operation of mounting a Tx filter and an Rx filter, according to an embodiment.

FIG. 8 is a view illustrating an operation of performing soldering for the substrate, according to an embodiment.

FIG. 9 is a view illustrating an operation of forming a molding part on the substrate, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

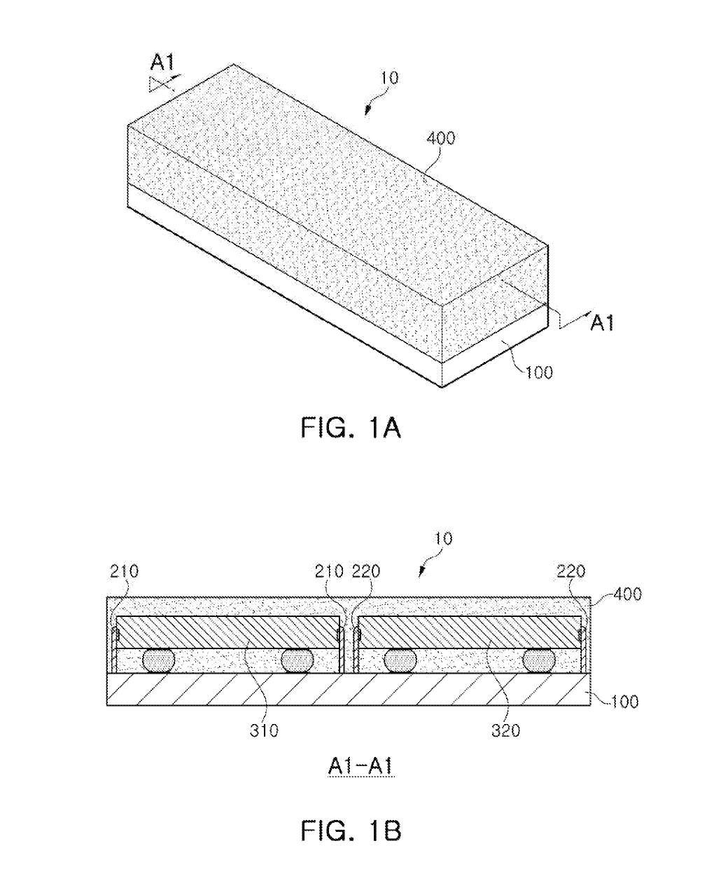

FIGS. 1A and 1B are an exterior perspective view and a cross-sectional view, respectively, of a BAW filter 10, according to an embodiment. Referring to FIGS. 1A and 1B, the BAW filter 10 includes a substrate 100, a first fixing member 210, a second fixing member 220, a transmission (Tx) filter 310, and a reception (Rx) filter 320. In addition, the BAW includes a molding part 400.

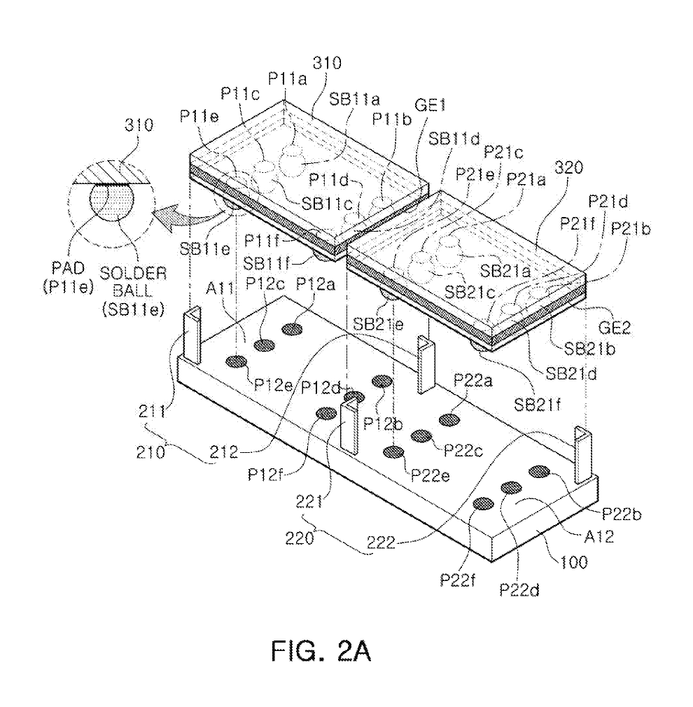

The substrate 100 includes a first mounting region A11 (FIG. 2A) and a second mounting region A12 (FIG. 2A) which are spaced apart from each other on a mounting surface of the substrate 100. As an example, the first mounting region A11 (FIG. 2A) and the second mounting region A12 (FIG. 2A) are spaced apart from each other by a predetermined interval, and the predetermined interval is approximately an interval in which physical interference between the Tx filter 310 and the Rx filter 320 does not occur when the Tx filter 310 and the Rx filter 320 are mounted at the time of manufacturing the BAW filter 10.

The first fixing member 210 is disposed adjacent to the first mounting region A11 (FIG. 2A) so as to accurately guide the Tx filter 310 to the first mounting region A11 (FIG. 2A). The second fixing member 220 is disposed adjacent to the second mounting region A12 (FIG. 2A) so as to accurately guide the Rx filter 320 to the second mounting region A12 (FIG. 2A).

The first fixing member 210 and the second fixing member 220 may be solder resistors including a conductive material. For example, the first fixing member 210 and the second fixing member 220 are melted in an atmosphere of a high temperature (e.g., 300° C.) and are then hardened, which allows the Tx filter 310 and the Rx filter 320 to be firmly fixed to the substrate 100.

As an example, the first fixing member 210 and the second fixing member 220 are formed of an alloy including tin, nickel, or copper, but are not limited to a specific material as long as the material of the first fixing member 210 and the second fixing member 220 includes the conductive material.

The Tx filter 310 is mounted on the first mounting region A11 (FIG. 2A) and is fixed in the first mounting region A11 by the first fixing member 210. The Rx filter 320 is mounted on the second mounting region A12 (FIG. 2A) and is fixed in the second mounting region A12 by the second fixing member 220. Accordingly, the Tx filter 310 and the Rx filter 320 may be accurately disposed on the first mounting region A11 (FIG. 2A) and the second mounting region A12 (FIG. 2A), respectively, by the first fixing member 210 and the second fixing member 220. As a result, physical interference between the Tx filter 310 and the Rx filter 320 does not occur at the time of mounting the Tx filter 310 and the Rx filter 320.

FIGS. 2A through 2C are exploded views illustrating example structures of the BAW filter 10.

Referring to FIGS. 1A and 1B, and FIG. 2A, according to an embodiment, the first fixing member 210 includes first and second fixing bodies 211 and 212 fixing at least two corners (e.g., two opposing diagonal corners) of the Tx filter 310 which are not adjacent to each other. As an example, the first and second fixing bodies 211 and 212 of the first fixing member 210 are disposed at opposing corners of the first mounting region A11 that face each other.

The second fixing member 220 includes first and second fixing bodies 221 and 222 fixing at least two corners (e.g., two opposing diagonal corners) of the Rx filter 320 which are not adjacent to each other. As an example, the first and second fixing bodies 221 and 222 of the second fixing member 220 are disposed at opposing corners of the second mounting region A12 that face each other.

Referring to FIGS. 1A, 1B and FIG. 2B, according to another embodiment, the first fixing member 210 includes first to fourth fixing bodies 211 to 214, fixing all of the corners of the Tx filter 310. As an example, the first to fourth fixing bodies 211 to 214 of the first fixing member 210 are disposed at respective corners of the first mounting region A11.

The second fixing member 220 includes first to fourth fixing bodies 221 to 224, fixing all of the corners of the Rx filter 320. As an example, the first to fourth fixing bodies 221 to 224 of the second fixing member 220 are disposed at respective corners of the second mounting region A12.

In the embodiments of FIGS. 2A and 2B, the fixing bodies 211 to 214 of the first fixing member 210 and the fixing bodies 221 to 224 of the second fixing member 220 are formed in a “┐” bracket form as a structure capable of fixing the corners of the Tx filter 310 and the Rx filter 320. However, the first and second fixing members 210 and 220 are not limited to the above-mentioned structures as long as the first fixing member 210 and the second fixing member 220 are able to fix the corners of the Tx filter 310 and the Rx filter 320.

Referring to FIGS. 1A, 1B and FIG. 2C, according to another embodiment, the first fixing member 210 includes the first to fourth fixing bodies 211 to 214 disposed between the respective corners of the first mounting region A11, and fixing respective sides of the Tx filter 310. As shown in FIG. 2C, the first to fourth fixing bodies 211 to 214 have a rectangular form.

The second fixing member 220 includes the first to fourth fixing bodies 221 to 224 disposed between the respective corners of the second mounting region A1, and fixing respective sides of the Rx filter 320. As shown in FIG. 2C, the first to fourth fixing bodies 221 to 224 have a rectangular form.

Since the Tx filter 310 and the Rx filter 320 may be formed to have the same structure or similar structures, a structure of the Tx filter 310 will be described, and a description of a structure of the Rx filter 320 will be omitted. Accordingly, it is to be understood that the following description of the structure of the Tx filter 310 also applies to the Rx filter 320.

In addition, although the BAW filter 10 is described as a BAW duplexer including the Tx filter 310 and the Rx filter 320, the BAW filter is not limited to such a configuration, and may be a BAW quadplexer including two Tx filters and two Rx filters. As such, the BAW filter 10 is not particularly limited with respect to the number of Tx or Rx filters included therein, and may include one or more Tx filters and one or more Rx filters.

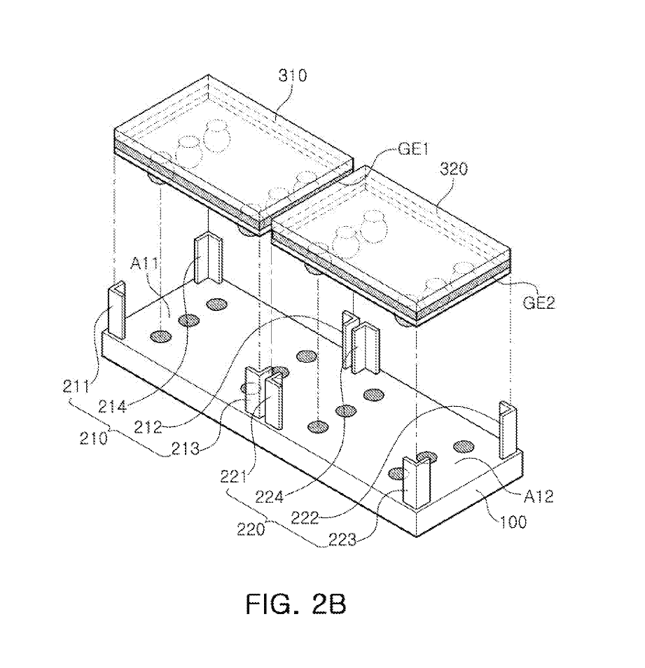

FIGS. 3A, 3B and 3C are a cross-sectional view, a side view, and a bottom view, respectively, illustrating an example of a structure of the BAW filter 10.

Referring to FIGS. 2A and 2B and to FIGS. 3A and 3B, according to an embodiment, the Tx filter 310 includes a filter structure, pads P11a and P11b connected to the filter structure and formed on a bottom surface of the Tx filter 310, solder balls SB11a and SB11b electrically connecting the pads P11a and P11b and the substrate 100 to each other, and a first ground electrode GE1 formed on a side of the Tx filter 310.

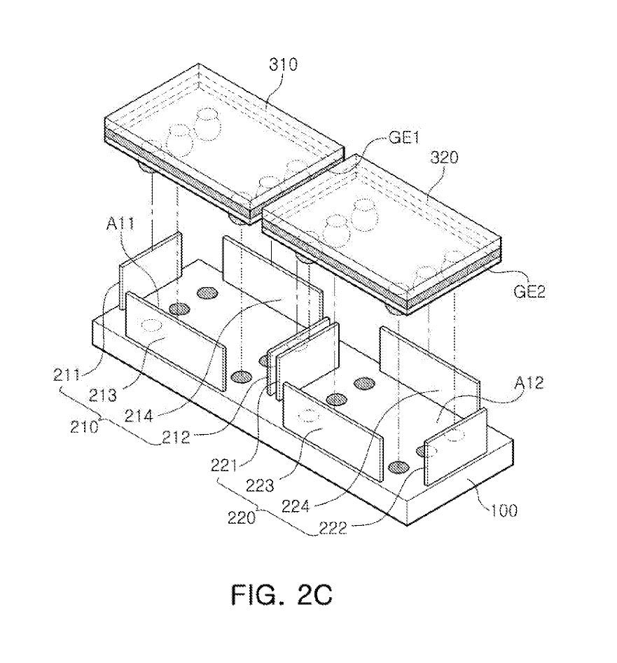

Referring to FIGS. 2A, 2B and to FIG. 3C, the Tx filter 310 further includes pads P11c to P11f formed on the bottom surface of the Tx filter 310. Thus, six pads P11a to P11f are formed on the bottom surface of the Tx filter 310. Some of the pads P11a to P11f are signal pads, while the remaining pads among the pads P11a to P11f are ground pads. The pads P11a to P11f are electrically connected to respective pads P12a to P12f (FIG. 4B) on the substrate 100 by six solder balls SB11a to SB11f. Although six pads P11a to P11f and six solder balls SB11a to SB11f are shown and described, the Tx filter 310 is not limited with respect to the number of pads and solder balls that may be included.

FIGS. 4A and 4B are a side view illustrating an example of a structure of the substrate 100 and a top view illustrating an example of the first mounting region A11 of the substrate 100, respectively.

Referring to FIGS. 4A and 4B, six pads P12a to P12f are formed on the first mounting region A11 of the substrate 100. Some of the six pads P12a to P12f are signal pads, and the remaining pads among the pads P12a to P12f are ground pads. Although six pads P12a and P12f are shown and described, the substrate 100 is not limited in the number of pads that may be included.

Referring to FIG. 2B and FIG. 4B, the pads P12a to P12f are electrically connected to the pads P11a to P11f, respectively, of the Tx filter 310 by the respective solder balls SB11a to SB11f.

Referring back to FIG. 2A, six pads P22a to P22f formed on the second mounting region A12 (FIG. 2A) of the substrate 100 are respectively electrically connected to six pads P21a to P21f on the Rx filter 320 by respective solder balls SB21a to SB21f.

In addition, as shown in FIGS. 2B, 4A and 4C, the Tx filter 310 includes the first ground electrode GE1 formed on the side of the Tx filter 310, the first fixing member 210 includes the conductive material, and the first ground electrode GE1 is electrically connected to the first fixing member 210. The Rx filter 320 includes a second ground electrode GE2 formed on a side of the Rx filter 320, the second fixing member 220 includes the conductive material, and the second ground electrode GE2 is electrically connected to the second fixing member 220. In this case, due to an increase in a size of a ground region, a signal shielding effect may be improved.

Referring to FIGS. 1A and 1B, the molding part 400 is formed on the substrate 100 so as to surround the Tx filter 310 and the Rx filter 320 which are mounted on the substrate 100. The molding part 400 protects the Tx filter 310 and the Rx filter 320 from external shock.

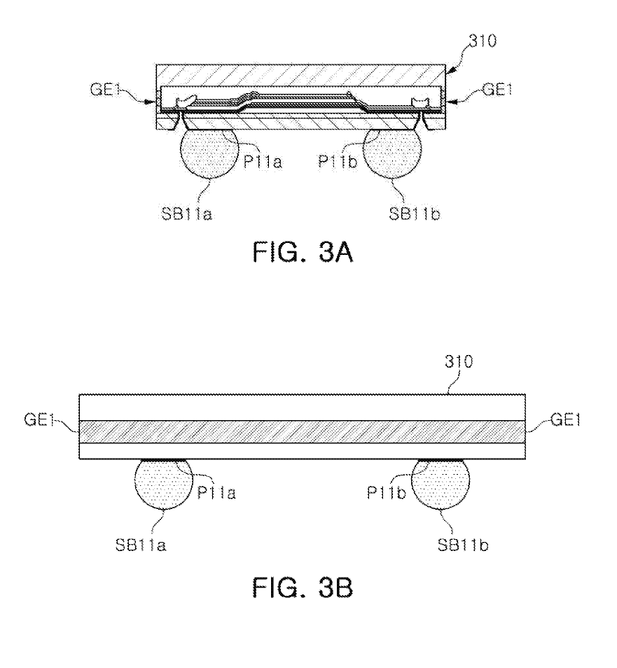

FIG. 5 is a flowchart illustrating a method for manufacturing the BAW filter 10, according to an embodiment. The method for manufacturing the BAW filter 10 will be described with reference to FIGS. 1A through 5.

Hereinafter, the description provided above with reference to FIGS. 1A through 4B may be applied to the description of the method for manufacturing the BAW filter 10. Therefore, a detailed description overlapping the description of the BAW filter 10 with respect to FIGS. 1A to 4B will be omitted.

Referring to FIG. 5, in operation S100, the substrate 100 is be prepared. The substrate 100 includes the first mounting region A11 and the second mounting region A12 which are spaced apart from each other, and further includes the first fixing member 210 disposed adjacent to the first mounting region A11 and the second fixing member 220 disposed adjacent to the second mounting region A12.

In operation S200, the Tx filter 310 and the Rx filter 320 are mounted on the substrate 100. The Tx filter 310 is fixed by the first fixing member 210 to be mounted on the first mounting region A11, and the Rx filter 320 is fixed by the second fixing member 220 to be mounted on the second mounting region A12.

In operation S300, soldering for the substrate 100, on which the Tx filter 310 and the Rx filter 320 are mounted, is performed. For example, the soldering is performed by a reflow machine, and the Tx filter 310 and the Rx filter 320 are firmly fixed to the substrate 100 by the reflow machine through an operation in which the first and second fixing members 210 and 220 are melted in an atmosphere of a high temperature of about 300° C., for example, and are then hardened. In this operation, the respective pads P11a to P11f and P21a-P21f (FIG. 2A) of the Tx filter 310 and the Rx filter 320 are attached to the respective pads of the substrate 100 through an operation in which the solder balls SB11a to SB11f and SB21a to SB21f are melted and are then hardened.

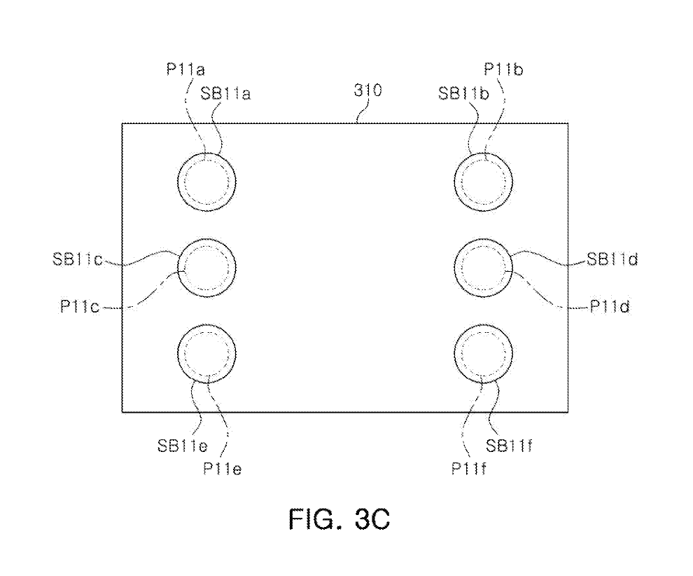

FIG. 6 is a view illustrating the operation S100 of preparing the substrate 100, according to an embodiment. Referring to FIGS. 1A through 6, in the operation S100, a multilayer substrate made of eight layers, for example, is used as the substrate 100, and a wiring and a component are mounted on the mounting surface of the substrate 100. In particular, the pads P12a to P12f are formed on the first mounting region A11 and the pads P22a to P22f (FIG. 2A) are formed on the second mounting region A12, as described above.

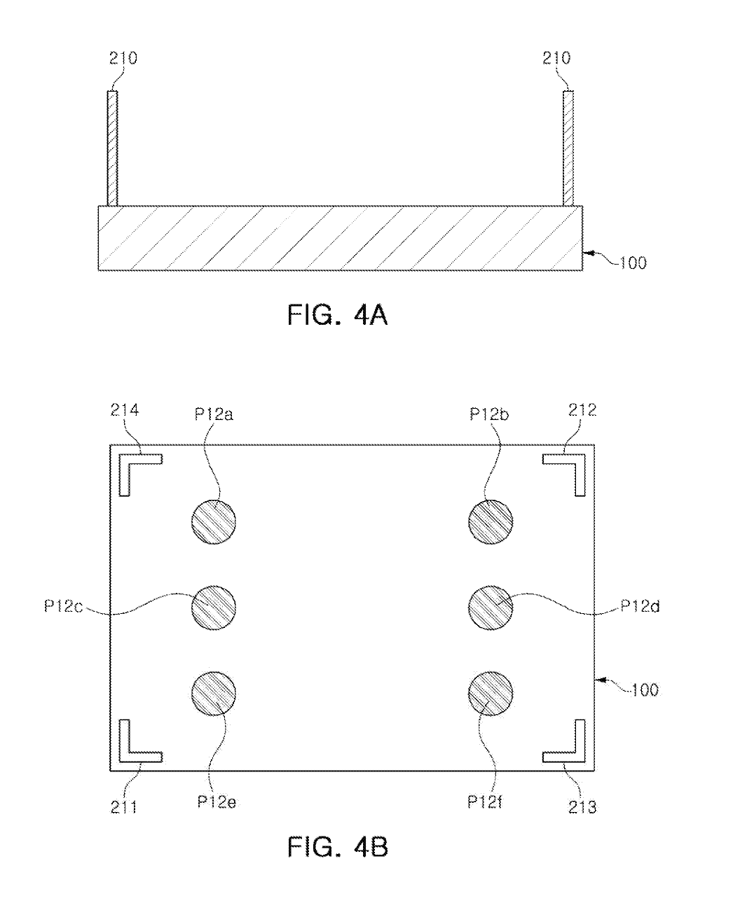

FIG. 7 is a view illustrating the operation S200 of mounting the Tx filter 310 and the Rx filter 320, according to an embodiment. Referring to FIGS. 1A through 7, in the operation S200, the Tx filter 310 is guided to the first mounting region A11 of the substrate 100 by the first fixing member 210, to be fixed to the first fixing member 210. The Rx filter 320 is guided to the second mounting region A12 of the substrate 100 by the second fixing member 220, to be fixed to the second fixing member 220.

In an example, in the operation S200, at least two corners of the Tx filter 310 which are not adjacent to each other are fixed by the first fixing member 210, and at least two corners of the Rx filter 320 which are not adjacent to each other are fixed by the second fixing member 220.

In another example, in the operation S200, the respective corners of the Tx filter 310 are fixed by the first fixing member 210, and the respective corners of the Rx filter 320 are fixed by the second fixing member 220.

In another example, at least two sides of the Tx filter 310 which are not adjacent to each other are fixed by the first fixing member 210, and at least two sides of the Rx filter 320 which are not adjacent to each other are fixed by the second fixing member 220.

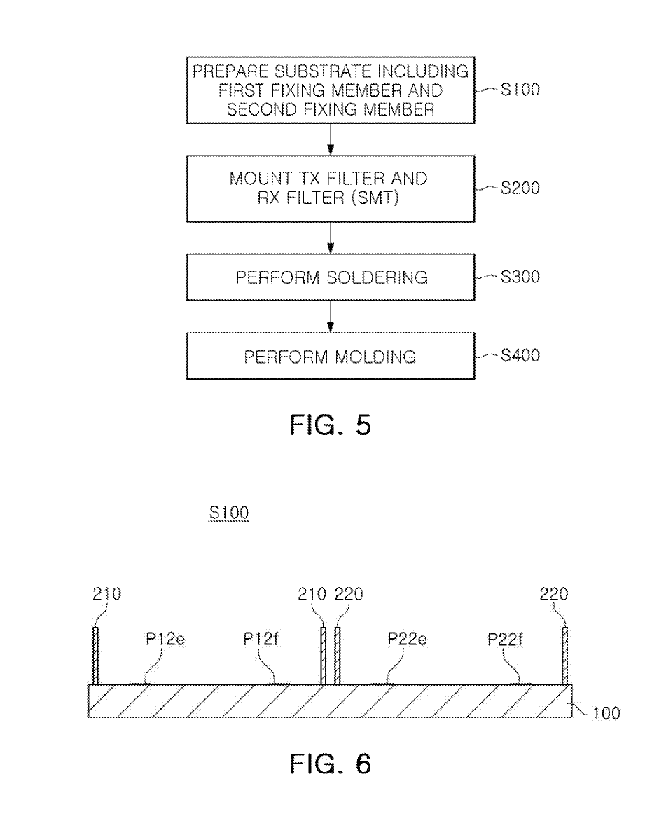

FIG. 8 is a view illustrating the operation S300 of performing soldering for the substrate 100, according to an embodiment. Referring to FIGS. 1A through 8, in the operation S300, the pads P12a to P12f formed on the first mounting region A11 of the substrate 100 and the pads P11a to P11f of the Tx filter 310 are electrically connected, respectively, by the solder balls SB11a to SB11f. The pads P22a to P22f formed on the second mounting region A12 of the substrate 100 are electrically connected to the respective pads P21a to P21f of the Rx filter 320 by the solder balls SB21a to SB21f.

In addition, in the operation S300, the first fixing member 210, including the conductive material, is electrically connected to the first ground electrode GE1 formed on the side of the Tx filter 310. In addition, the second fixing member 220, including the conductive material, is electrically connected to the second ground electrode GE2 formed on the side of the Rx filter 320.

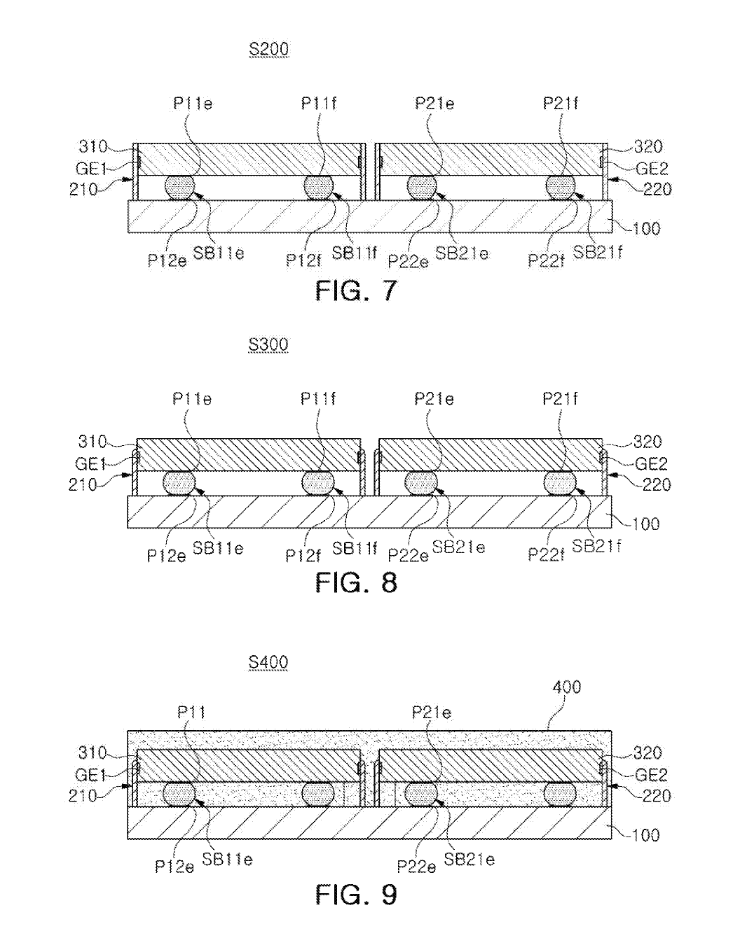

FIG. 9 is a view illustrating the operation S400 of forming the molding part 400 on the substrate 100, according to an embodiment. Referring to FIGS. 1A through 9, in the operation S400, the molding part 400 is formed on the substrate 100 such that the molding part 400 surrounds the Tx filter 310 and the Rx filter 320.

As set forth above, according to the embodiments disclosed herein, a Tx filter and an Rx filter of a BAW filter may be accurately mounted on respective defined mounting regions of a substrate, by fixing members guiding the Tx filter and the Rx filter to the defined mounting regions. Accordingly, the BAW filter may be compactly manufactured, and interference between the Tx filter and the Rx filter may be reduced at the time of mounting the Tx filter and the Rx filter on the substrate.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave (BAW) filter comprising:
a substrate comprising a first mounting region and a second mounting region which are spaced apart from each other;
a first fixing member disposed adjacent to the first mounting region;
a second fixing member disposed adjacent to the second mounting region;
a Tx filter mounted on the first mounting region and fixed by the first fixing member; and
an Rx filter mounted on the second mounting region and fixed by the second fixing member.

2. The BAW filter of claim 1, wherein:
the first fixing member fixes two sides of the Tx filter which are not adjacent to each other; and
the second fixing member fixes two sides of the Rx filter which are not adjacent to each other.

3. The BAW filter of claim 1, wherein:
the first fixing member fixes two corners of the Tx filter which are not adjacent to each other; and
the second fixing member fixes two corners of the Rx filter which are not adjacent to each other.

4. The BAW filter of claim 1, wherein:
the first fixing member fixes corners of the Tx filter; and
the second fixing member fixes corners of the Rx filter.

5. The BAW filter of claim 1, wherein:
pads formed on the first mounting region are electrically connected to respective pads on the Tx filter; and
pads formed on the second mounting region are electrically connected to respective pads on the Rx filter.

6. The BAW filter of claim 1, wherein:
the first fixing member comprises a conductive material; and
the Tx filter comprises a first ground electrode formed on a side of the Tx filter and electrically connected to the first fixing member.

7. The BAW filter of claim 1, wherein:
the second fixing member includes a conductive material; and
the Rx filter comprises a second ground electrode formed on a side of the Rx filter and electrically connected to the second fixing member.

8. The BAW filter of claim 1, further comprising a molding part formed on the substrate and surrounding the Tx filter and the Rx filter.

9. The BAW filter of claim 1, wherein the first fixing member and the second fixing member comprise bodies having a bracket form.

10. The BAW filter of claim 1, wherein the first fixing member and the second fixing member comprise bodies having a rectangular form.

11. A method to manufacture a bulk acoustic wave (BAW) filter, the method comprising:
preparing a substrate comprising
a first mounting region and a second mounting region which are spaced apart from each other,
a first fixing member disposed adjacent to the first mounting region, and
a second fixing member disposed adjacent to the second mounting region;
mounting a Tx filter on the first mounting region such that the Tx filter is fixed by the first fixing member;
mounting an Rx filter on the second mounting region such that the Rx filter is fixed by the second fixing member; and
performing soldering for the substrate.

12. The method of claim 11, wherein:
in the mounting of the Tx filter, the first fixing member fixes two sides of the Tx filter which are not adjacent to each other; and
in the mounting of the Rx filter, the second fixing member fixes two sides of the Rx filter which are not adjacent to each other.

13. The method of claim 11, wherein:
in the mounting of the Tx filter, the first fixing member fixes two corners of the Tx filter which are not adjacent to each other; and
in the mounting of the Rx filter, the second fixing member fixes two corners of the Rx filter which are not adjacent to each other.

14. The method of claim 11, wherein:
in the mounting of the Tx filter, the first fixing member fixes all corners of the Tx filter; and
in the mounting of the Rx filter, the second fixing member fixes all corners of the Rx filter.

15. The method of claim 11, wherein the performing of the soldering for the substrate comprises:
electrically connecting pads on the first mounting region to pads on the Tx filter, by solder; and
electrically connecting pads on the second mounting region to pads on the Rx filter, by the solder.

16. The method of claim 11, wherein the performing of the soldering for the substrate comprises:
electrically connecting the first fixing member and a first ground electrode, formed on a side of the Tx filter, to each other.

17. The method of claim 11, wherein the performing of the soldering for the substrate comprises:
electrically connecting the second fixing member and a second ground electrode, formed on a side of the Rx filter, to each other.

18. The method of claim 11, further comprising forming a molding part on the substrate such that the molding part surrounds the Tx filter and the Rx filter.
